(19) United States
(12) Patent Application Publication
(10) Pub. No.: US 2025/0024684 A1
(43) Pub. Date: Jan. 16, 2025

(54) VERTICAL SEMICONDUCTOR DEVICE

(71) Applicant: SAMSUNG ELECTRONICS CO., LTD., Suwon-Si (KR)

(72) Inventors: Sanghyun PARK, Suwon-si (KR); Hyuncheol KIM, Suwon-si (KR); Suhwan LIM, Suwon-si (KR); Siyeon CHO, Suwon-si (KR)

(21) Appl. No.: 18/672,512

(22) Filed: May 23, 2024

(30) Foreign Application Priority Data
Jul. 14, 2023 (KR) 10-2023-0091431

(51) Int. Cl. H10B 51/20; H10B 51/30

(52) U.S. Cl. CPC H10B 51/20; H10B 51/30

(57) ABSTRACT

A vertical semiconductor device includes a substrate, a stacked structure including a plurality of insulation patterns and a plurality of gate electrode structures alternately and repeatedly stacked on the substrate in a vertical direction substantially perpendicular to a surface of the substrate, a channel pattern passing through the stacked structure, a gate insulation layer surrounding an outer wall of the channel pattern, and a gate insulation pattern disposed between the gate insulation layer and the gate electrode structures. The gate insulation layer includes a metal oxide having paraelectricity, and the gate insulation pattern has ferroelectricity. The gate insulation layer includes a first portion contacting one of the insulation patterns and a second portion contacting the gate insulation pattern.

### CROSS-REFERENCE TO RELATED APPLICATIONS

This application claims priority under 35 U.S.C. § 119 to Korean Patent Application No. 10-2023-0091431, filed on Jul. 14, 2023 in the Korean Intellectual Property Office, the disclosure of which is incorporated by reference herein in its entirety.

### TECHNICAL FIELD

Example embodiments of the present inventive concept relate to a vertical semiconductor device. More particularly, example embodiments of the present inventive concept relate to a vertical non-volatile memory device in which cells are stacked in a vertical direction.

### DISCUSSION OF THE RELATED ART

For high integration of a memory device, a vertical memory device in which memory cells are stacked in a vertical direction has been presented. In the vertical memory device, the resistance of a layer included in a memory cell among a plurality of memory cells may be changed so that data may be written in the memory cell. Since the memory cells in the vertical memory device are closely arranged relative to each other, an operation failure of the vertical memory device may occur due to interference between adjacent memory cells.

### SUMMARY

Example embodiments of the present inventive concept provide a vertical semiconductor device including memory cells stacked in a vertical direction.

According to an example embodiment of the present inventive concept, a vertical semiconductor device includes a substrate, a stacked structure including a plurality of insulation patterns and a plurality of gate electrode structures alternately and repeatedly stacked on the substrate in a vertical direction substantially perpendicular to a surface of the substrate, a channel pattern passing through the stacked structure, and a gate insulation layer surrounding an outer wall of the channel pattern. The gate insulation layer includes a metal oxide having paraelectricity. The vertical semiconductor device further includes a gate insulation pattern disposed between the gate insulation layer and the gate electrode structures, the gate insulation pattern having ferroelectricity. The gate insulation layer includes a first portion contacting the insulation pattern and a second portion contacting the gate insulation pattern.

According to an example embodiment of the present inventive concept, a vertical semiconductor device includes a substrate, a stacked structure including a plurality of insulation patterns and a plurality of gate electrode structures alternately and repeatedly stacked on the substrate in a vertical direction substantially perpendicular to a surface of the substrate, a channel pattern passing through the stacked structure, and a gate insulation layer surrounding an outer wall of the channel pattern. The gate insulation layer includes a metal oxide having paraelectricity and not having a dopant, and a first portion of the gate insulation layer facing the gate electrode structure includes a first recess in a direction toward the channel pattern. The vertical semiconductor device further includes a gate insulation pattern disposed in the first recess, the gate insulation pattern having ferroelectricity. The first portion the gate insulation layer facing the gate electrode structure has a thickness less than a thickness of the gate insulation pattern.

According to an example embodiment of the present inventive concept, a vertical semiconductor device includes a substrate, a stacked structure including a plurality of insulation patterns and a plurality of gate electrode structures alternately and repeatedly stacked on the substrate in a vertical direction substantially perpendicular to a surface of the substrate, a channel pattern passing through the stacked structure, and a gate insulation layer surrounding an outer wall of the channel pattern. The gate insulation layer includes hafnium oxide having paraelectricity and not having a dopant, and a first portion of the gate insulation layer facing the gate electrode structure includes a first recess in a direction toward the channel pattern. The vertical semiconductor further includes a gate insulation pattern disposed in the first recess of the first gate insulation, the gate insulation pattern having ferroelectricity. The gate insulation pattern includes a plurality of hafnium oxide layers and a plurality of doped layers alternately stacked.

In example embodiments, in the vertical semiconductor device, a gate insulation layer having paraelectricity and a gate insulation pattern facing a gate electrode structure and having ferroelectricity may be formed, respectively. Accordingly, defects due to interference between the memory cells in the vertical semiconductor device may be decreased.

### BRIEF DESCRIPTION OF THE DRAWINGS

The above and other features of the present inventive concept will become more apparent by describing in detail example embodiments thereof, with reference to the accompanying drawings, in which:

FIG. 1 is a cross-sectional view illustrating a vertical semiconductor device in accordance with an example embodiment of the present inventive concept;

FIG. 2A is an enlarged view of a portion of a memory cell in a vertical semiconductor device in accordance with an example embodiment of the present inventive concept;

FIG. 2B is an enlarged view of a portion of a memory cell in a vertical semiconductor device in accordance with an example embodiment of the present inventive concept;

FIG. 3 is an enlarged view of a memory cell portion in a vertical semiconductor device in accordance with an example embodiment of the present inventive concept;

FIG. 4 is an enlarged view of a memory cell portion of a vertical semiconductor device in accordance with an example embodiment of the present inventive concept;

FIG. 5 is a cross-sectional view illustrating a vertical semiconductor device in accordance with an example embodiment of the present inventive concept;

FIGS. 6 to 16 are cross-sectional views illustrating a method of manufacturing a vertical semiconductor device in accordance with an example embodiment of the present inventive concept;

FIG. 17 is a cross-sectional view illustrating a vertical semiconductor device in accordance with an example embodiment of the present inventive concept; and

FIGS. 18 and 19 are cross-sectional views illustrating a method of manufacturing a vertical semiconductor device in accordance with an example embodiment of the present inventive concept.

### DETAILED DESCRIPTION OF THE EMBODIMENTS

Example embodiments of the present inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an example embodiment may be described as a “second” element in another example embodiment.

It should be understood that descriptions of features or aspects within each example embodiment should typically be considered as available for other similar features or aspects in other example embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

It will be further understood that when two components or directions are described as extending substantially parallel or perpendicular to each other, the two components or directions extend exactly parallel or perpendicular to each other, or extend approximately parallel or perpendicular to each other within a measurement error as would be understood by a person having ordinary skill in the art.

Hereinafter, a direction parallel to a surface of a substrate is referred to as a first direction, and a direction parallel to the surface of the substrate and vertically crossing the first direction is referred to as a second direction. In addition, a direction vertical to the surface of the substrate is referred to as a vertical direction.

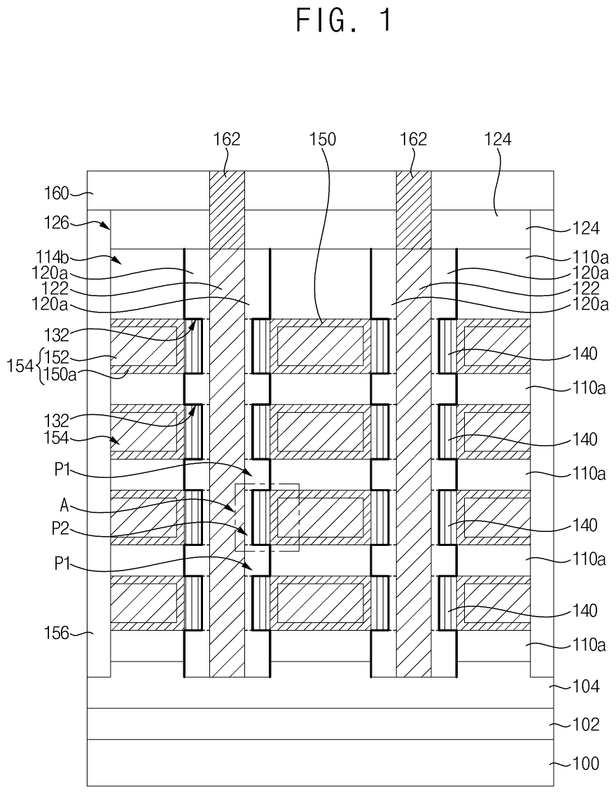

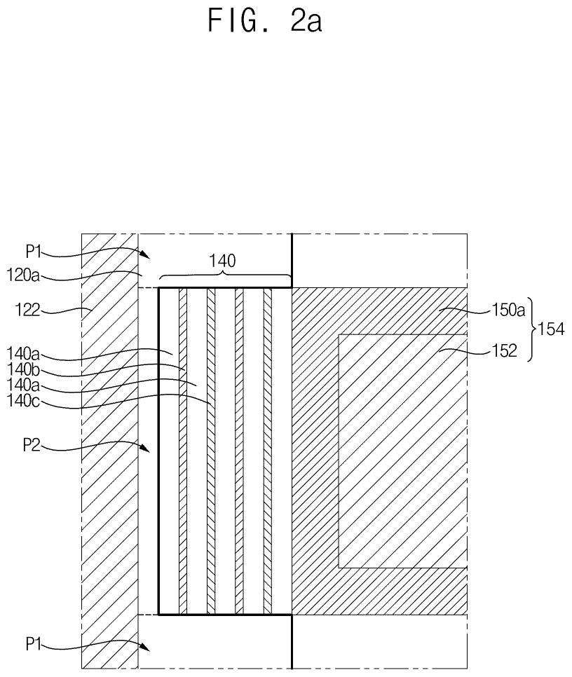

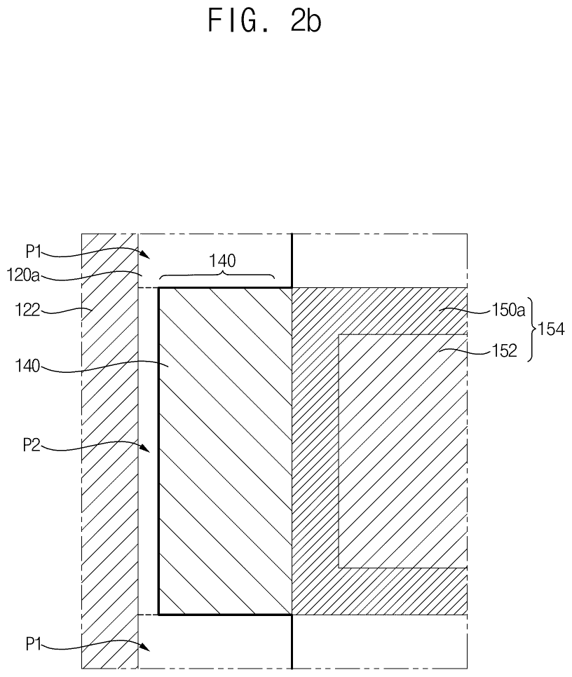

FIG. 1 is a cross-sectional view illustrating a vertical semiconductor device in accordance with an example embodiment of the present inventive concept. FIG. 2A is an enlarged view of a portion of a memory cell in a vertical semiconductor device in accordance with an example embodiment of the present inventive concept. FIG. 2B is an enlarged view of a portion of a memory cell in a vertical semiconductor device in accordance with an example embodiment of the present inventive concept.

Referring to FIGS. 1 and 2A, a vertical semiconductor device may be formed on a substrate 100. The substrate 100 may include a semiconductor material such as, for example, silicon, germanium, or silicon-germanium, or a group III-V compound such as GaP, GaAs, or GaSb. In some example embodiments, the substrate 100 may be a silicon-on-insulator (SOI) substrate or a germanium-on-insulator (GOI) substrate. However, the substrate 100 is not limited thereto.

A lower circuit pattern may be formed on the substrate 100, and a lower insulating interlayer 102 may cover the lower circuit pattern. The lower circuit pattern may include, e.g., a transistor and wiring. The lower circuit pattern may serve peripheral circuits in the vertical semiconductor device.

A common source plate (CSP) 104 may be disposed on the lower insulating interlayer 102. The common source plate 104 may include, e.g., a semiconductor material doped with impurities, a metal, a conductive metal nitride, or a metal silicide. An upper portion of the common source plate 104 may include the semiconductor material doped with impurities. For example, the common source plate 104 may include polysilicon doped with n-type impurities.

A stacked structure 114b may be disposed on the common source plate 104. The stacked structure 114b may have a structure in which insulation patterns 110a and gate electrode structures 154 are alternately and repeatedly stacked. A channel pattern 122 may pass through the stacked structure 114b. A gate insulation layer 120a and a gate insulation pattern 140 may be disposed on an outer wall of the channel pattern 122.

In some example embodiments, the stacked structure 114b may contact the substrate 100 (e.g., may directly contact the substrate 100), and the common source plate 104 may not be formed. Additionally, circuit patterns constituting peripheral circuits may be disposed in an area of the substrate 100 besides the stacked structure 114b.

The stacked structure 114b may extend in a first direction. A first insulating interlayer 124 may be formed on the stacked structure 114b and the channel pattern 122. A trench 126 may pass through the first insulating interlayer 124 and the stacked structure 114b, and may extend in the first direction. A plurality of the stacked structures 114b may be formed, and the trench 126 may be disposed between the stacked structures 114b.

The channel pattern 122 may vertically extend to an upper portion of the common source plate 104. In example embodiments, the channel pattern 122 may have a pillar shape. In example embodiments, the channel pattern 122 may contact the common source plate 104. The channel pattern 122 may include a semiconductor material. The channel pattern 122 may include, e.g., polysilicon doped with impurities, silicon doped with carbon, or an oxide semiconductor.

The gate insulation layer 120a may surround an outer wall of the channel pattern 122. The gate insulation layer 120a may contact the channel pattern 122.

The gate insulation layer 120a may include a metal oxide having a dielectric constant higher than a dielectric constant of silicon nitride.

In example embodiments, the gate insulation layer 120a may include a metal oxide that has ferroelectricity depending on a crystal structure thereof. The gate insulation layer 120a may include, e.g., hafnium oxide.

In some example embodiments, the gate insulation layer 120a may include, e.g., ZrO2 or Al2O3.

The gate insulation layer 120a may include a first portion P1 laterally facing the insulation pattern 110a and a second portion P2 laterally facing the gate electrode structure 154. The first portion P1 and the second portion P2 may be alternately arranged in the vertical direction. The first portion P1 may have a first thickness, and the second portion P2 may have a second thickness less than the first thickness. In example embodiments, the second thickness may be less than about ⅕ of the first thickness. Accordingly, a first recess 132 may be formed on the second portion P2 of the gate insulation layer 120a by a difference between the thickness of the first portion P1 and the thickness of the second portion P2.

In example embodiments, the first and second portions P1 and P2 of the gate insulation layer 120a may include a first metal oxide layer that may have paraelectricity and that is not doped with dopants (e.g., impurities). In example embodiments, the first and second portions P1 and P2 of the gate insulation layer 120a may include hafnium oxide that may have the paraelectricity and is not doped with dopants.

The first and second portions P1 and P2 of the gate insulation layer 120a may be the hafnium oxide having a crystal structure other than an orthorhombic crystal. The hafnium oxide may have, e.g., tetragonal crystals, monoclinic crystals, or triclinic crystals.

The gate insulation pattern 140 may be laterally stacked on the second portion P2 of the gate insulation layer 120a. The gate electrode structure 154 may fill a space between neighboring insulation patterns 110a in the vertical direction, and may be formed on surfaces of the neighboring insulation patterns 110a in the vertical direction and the gate insulation pattern 140.

The gate insulation pattern 140 may have ferroelectricity. A first surface, that is, a surface facing the channel pattern, of the gate insulation pattern 140 may contact the second portion P2 of the gate insulation layer 120a. Hereinafter, the first surface of a layer or a pattern may be a surface facing the channel pattern 122. However, in example embodiments, the first surface of the gate insulation pattern 140 does not contact the first portion P1 of the gate insulation layer 120a.

In example embodiments, the gate insulation pattern 140 may include a second metal oxide layer 140a and doped layers 140b and 140c that may have ferroelectricity depending on a crystal structure thereof. The doped layer 140b and 140c may serve as dopants that induce the second metal oxide layer 140a to have ferroelectricity. The second metal oxide layer 140a may be a ferroelectric metal oxide layer that may have ferroelectricity depending on a crystal structure thereof.

As shown in FIG. 2A, the gate insulation pattern 140 may include the second metal oxide layers 140a and doped layers 140b and 140c alternately stacked. In this case, each of the second metal oxide layers 140a may have a thickness greater than a thickness of each of the doped layers 140b and 140c. By adjusting the thicknesses of the doped layers 140b and 140c, the amount of dopants included in the gate insulation pattern 140 may be adjusted.

In addition, the thickness of the gate insulation pattern 140 may be greater than a thickness of the second portion P2 of the gate insulation layer 120a. The gate insulation pattern 140 may have a thickness sufficient to have ferroelectricity. The gate insulation pattern may have a thickness serving as a data storage layer. Accordingly, the gate insulation pattern 140 may have a thickness of about 50 Å to about 200 Å.

The doped layers 140b and 140c may be oxide layers of a material used as dopants. The dopants may include, e.g., silicon (Si), zirconium (Zr), aluminum (Al), yttrium (Y), lanthanum (La), carbon (C), nitrogen (N), germanium (Ge), and tin (Sn).), strontium (Sr), lead (Pb), calcium (Ca), barium (Ba), titanium (Ti), zirconium (Zr), gadolinium (Gd), etc.

In example embodiments, in the gate insulation pattern 140, each of the second metal oxide layers may be a hafnium oxide layer 140a, and the doped layers may include a zirconium oxide layer 140b and a silicon oxide layer 140c. For example, the gate insulation pattern 140 may have a stacked structure including the hafnium oxide layer 140a/the zirconium oxide layer 140b/the hafnium oxide layer 140a/the silicon oxide layer 140c repeatedly stacked. In this case, the thickness of each of the hafnium oxide layers 140a may be greater than the thickness of each of the zirconium oxide layers 140b, and may be greater than the thickness of the each of the silicon oxide layers 140c.

In some example embodiments, as shown in FIG. 2B, the gate insulation pattern 140 may include a ferroelectric material having a perovskite structure. For example, the gate insulation pattern 140 may include SrBi2Ta2O9 (hereinafter referred to as SBT), (Bi,La)4Ti3O12 (hereinafter referred to as BLT), or (Pb,Zr)TiO3 (hereinafter referred to as PZT). In some example embodiments, the gate insulation pattern 140 may include hafnium zirconium oxide.

The gate insulation pattern 140 may sufficiently fill the first recess. In example embodiments, a surface of the gate insulation pattern 140 may be vertically aligned with a first surface of the first portion P1 of the gate insulation layer 120a. In some example embodiments, the surface of the gate insulation pattern 140 may slightly and laterally protrude from the first surface of the first portion P1 of the gate insulation layer 120a.

The gate electrode structure 154 may fill the space between the insulation patterns 110a. The gate electrode structure 154 may include metal or polysilicon. When the gate electrode structure 154 includes metal, the gate electrode structure 154 may include a barrier metal pattern 150a and a metal pattern 152. The barrier metal pattern 150a may be disposed on surfaces of the neighboring insulation patterns 110a and the gate insulation pattern 140, and may surround the metal pattern 152. In example embodiments, the metal pattern 152 may include, e.g., tungsten, and the barrier metal pattern 150a may include, e.g., titanium, titanium nitride, tantalum, or tantalum nitride.

The trench 126 disposed between the stacked structures 114b may extend vertically into an upper portion of the common source plate 104. A filling insulation pattern 156 may fill the trench 126. The filling insulation pattern 156 may include, e.g., silicon oxide or silicon nitride.

A second insulating interlayer 160 may cover the first insulating interlayer 124 and the filling insulation pattern 156. A connection pattern 162 may pass through the first and second insulating interlayers 124 and 160, and may contact an upper surface of the channel pattern 122.

As described above, each of the memory cells may have the second portion P2 of the gate insulation layer 120a, the gate insulation pattern 140, and the gate electrode structure 154 laterally stacked on the sidewall of the channel pattern 122. The second portions P2 of the gate insulation layer 120a and the gate insulation pattern 140 may be disposed between the channel pattern 122 and the gate electrode structure 154. The first and second portions P1 and P2 of the gate insulation layer 120a may include the first metal oxide layer that may have paraelectricity and does not include containing dopants. The gate insulation pattern 140 may include the doped layers and the second metal oxide layers 140a having the ferroelectricity. In some example, the gate insulation pattern 140 may include, e.g., a ferroelectric material.

The gate insulation layer 120a having the paraelectricity and is not doped with dopants, and the gate insulation pattern 140 having ferroelectricity may be disposed, respectively. Accordingly, undesired ferroelectric polarization in the first portion P1 of the gate insulation layer 120a may be decreased. In addition, the second portion P2 of the gate insulation layer 120a may serve as an interface layer having a high dielectric constant. As a result, reliability failure caused by an electric field concentration at an area adjacent to the channel pattern 122 may be decreased.

The vertical semiconductor device having the above structure can be operated as follows.

A programming voltage may be applied to the gate electrode structure 154, and the channel pattern 122 may maintain a ground voltage. In this case, the electrical dipole in the gate insulation pattern 140 facing the gate electrode structure 154 may be polarized. For example, the electric dipole may have a first polarization direction in which an area adjacent to the gate electrode structure 154 may be a cathode (e.g., negative electrode) and an area adjacent to the channel pattern 122 may be an anode (e.g., positive electrode). In this case, a threshold voltage of a cell transistor corresponding to the gate electrode structure 154 may be lowered by the electric dipole. Thereafter, although a voltage is not supplied the gate electrode structure 154, the gate insulation pattern 140 may maintain a dipole polarization state having the first polarization direction.

Conversely, a ground voltage may be applied to the gate electrode structure 154, and an erase voltage may be applied to the channel pattern 122. In this case, the electrical dipole in the gate insulation pattern 140 facing the gate electrode structure 154 may be polarized to have a second polarization direction opposite to the first polarization direction. For example, the area adjacent to the gate electrode structure 154 may be the anode and the area adjacent to the channel pattern 122 may be the cathode. In this case, the threshold voltage of the cell transistor corresponding to the gate electrode structure 154 may be increased.

If at least portion of the first portion P1 of the gate insulation layer 120a has ferroelectricity, the first portion P1 of the gate insulation layer 120a may also be polarized. Therefore, a failure of the memory cell may occur due to interference between memory cells adjacent to the first portion P1 of the gate insulation layer 120a. However, in example embodiments, the first portion P1 of the gate insulation layer 120a does not include dopants that induce the first portion P1 of the gate insulation layer 120a having ferroelectricity. Therefore, the first portion P1 of the gate insulation layer 120a does not have ferroelectricity, but rather, has paraelectricity. Therefore, in example embodiments, the first portion P1 of the gate insulation layer 120a is not polarized, and as a result, defects due to interference between adjacent cell transistors may be decreased.

In example embodiments, the first portion P1 of the gate insulation layer 120a does not directly contact the gate electrode structure 154. Accordingly, the first portion P1 of the gate insulation layer 120a does not have ferroelectricity. Thus, leakage currents generated at an interface between the first portion P1 of the gate insulation layer 120a and the gate electrode structure 154 may be decreased.

In example embodiments, the second portion P2 of the gate insulation layer 120a does not have ferroelectricity. As a result, the second portion P2 of the gate insulation layer 120a serving as the interface layer may have a high dielectric constant. Accordingly, the reliability failure caused by the electric field concentration at an area adjacent to the channel pattern 122 may be decreased.

In some example embodiments, the memory cell may have the structure including the second portion P2 of the gate insulation layer 120a, the gate insulation pattern 140, the gate electrode structure 154, and some additional layers. Hereinafter, the memory cells having various stacked structures according to example embodiments is described.

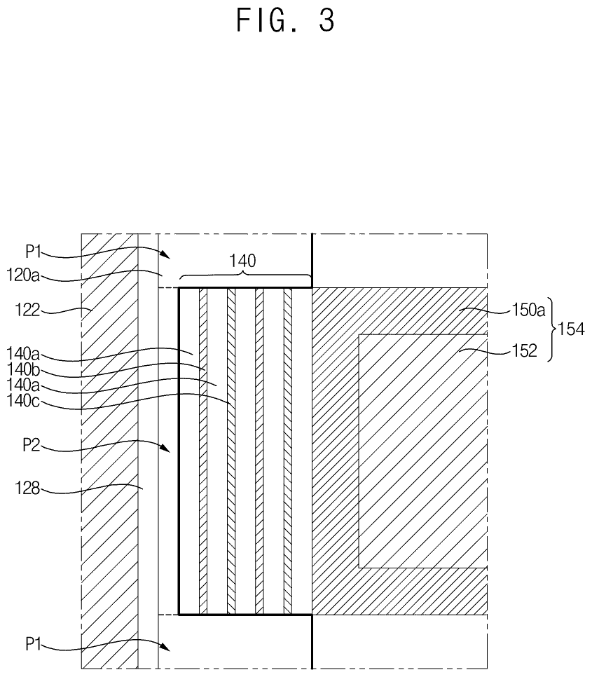

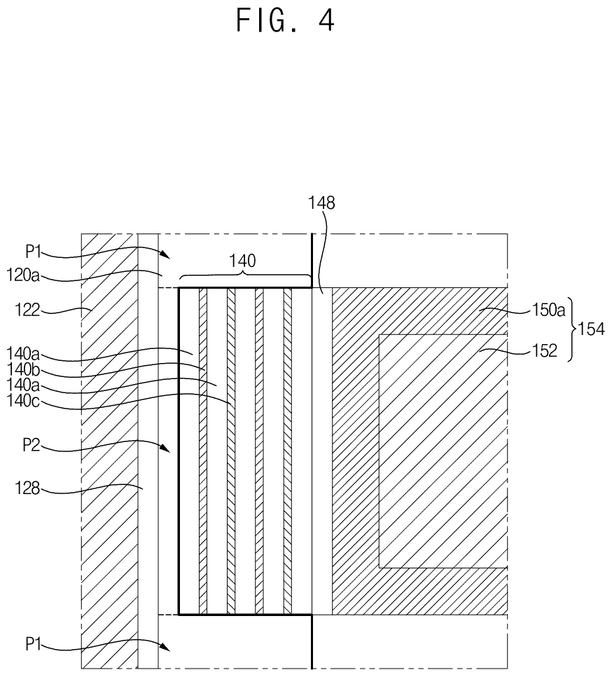

FIG. 3 is an enlarged view of a memory cell portion in a vertical semiconductor device in accordance with an example embodiment of the present inventive concept. FIG. 4 is an enlarged view of a memory cell portion of a vertical semiconductor device in accordance with an example embodiment of the present inventive concept.

Referring to FIG. 3, the vertical semiconductor device may further include a first interface insulation layer 128 disposed between the channel pattern 122 and the gate insulation layer 120a in the vertical semiconductor device shown in FIG. 1. The first interface insulation layer 128 may surround an outer wall of the channel pattern 122.

The first interface insulation layer 128 may include, e.g., silicon oxide or aluminum oxide. The first interface insulation layer 128 may be an adhesion layer disposed between the gate insulation layer 120a and the channel pattern 122. The first interface insulation layer 128 may have a uniform thickness.

Each of the memory cells may include the first interface insulation layer 128, the second portion P2 of the gate insulation layer 120a, and the gate insulation pattern 140 and the gate electrode structure 154 laterally stacked on the sidewall of the channel pattern 122. The first interface insulation layer 128, the second portion P2 of the gate insulation layer 120a, and the gate insulation pattern 140 may be disposed between the channel pattern 122 and the gate electrode structure 154.

Referring to FIG. 4, the vertical semiconductor device may further include a first interface insulation layer 128 and a second interface insulation layer 148 in the vertical semiconductor device shown in FIG. 1. The first interface insulation layer 128 may be disposed between the channel pattern 122 and the gate insulation layer 120a in the vertical semiconductor device shown in FIG. 1, and the second interface insulation layer 148 may be disposed between the gate insulation pattern 140 and the gate electrode structure 154 in the vertical semiconductor device shown in FIG. 1. The first interface insulation layer 128 may surround an outer wall of the channel pattern 122. The second interface insulation layer 148 may contact at least the gate insulation pattern 140. For example, in an example embodiment, the second interface insulation layer 148 may be disposed on a surface of the gate insulation pattern 140 in the first gap. For example, in an example embodiment, the second interface insulation layer 148 may be conformally disposed on surfaces of the gate insulation pattern 140 and the insulation pattern 110a in the first gap.

The first and second interface insulation layers 128 and 148 may include, e.g., silicon oxide or aluminum oxide. The first interface insulation layer 128 may be an adhesion layer disposed between the gate insulation layer 120a and the channel pattern 122. The second interface insulation layer 148 may block charges injected into the gate electrode structure 154. As a result, leakage currents may be decreased.

Each of the memory cells may include the first interface insulation layer 128, the second portion P2 of the gate insulation layer 120a, the gate insulation pattern 140, the second interface insulation layer 148, and the gate electrode structure 154 laterally stacked on the sidewall of the channel pattern 122. The first interface insulation layer 128, the second portion P2 of the gate insulation layer 120a, the gate insulation pattern 140, and the second interface insulation layer 148 may be disposed between the channel pattern 122 and the gate electrode structure 154.

The vertical semiconductor device may include a structure constituting the memory cell, and other elements may be variously modified.

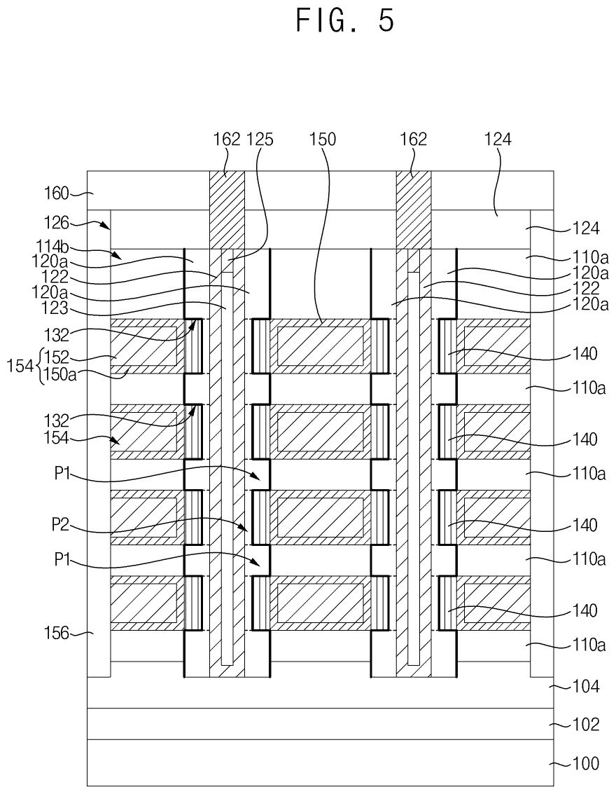

FIG. 5 is a cross-sectional view illustrating a vertical semiconductor device in accordance with an example embodiment of the present inventive concept.

The vertical semiconductor device described with reference to FIG. 5 is the same as the vertical semiconductor device described with reference to FIG. 1, except for the structure of a channel pattern.

Referring to FIG. 5, the channel pattern 122 may extend vertically to an upper portion of the common source plate 104. In example embodiments, the channel pattern 122 may have a cylindrical shape. For example, the channel pattern 122 may include polysilicon doped with impurities.

A second filling insulation pattern 123 may fill an inner space of the channel pattern 122. An upper capping pattern 125 may be formed on the second filling insulation pattern 123, and may contact an upper portion of the channel pattern 122. The upper capping pattern 125 may fill the space of the upper portion of the channel pattern 122. For example, the upper capping pattern 125 may include polysilicon doped with impurities.

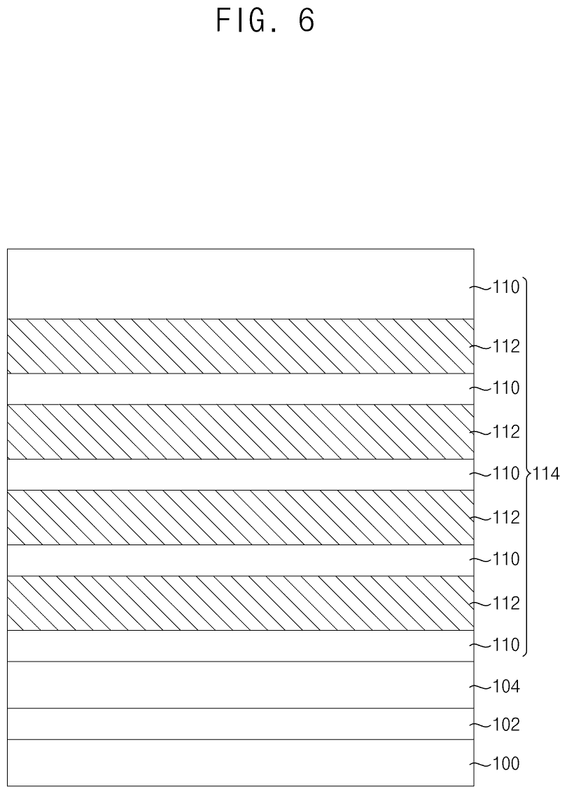

FIGS. 6 to 16 are cross-sectional views illustrating a method of manufacturing a vertical semiconductor device in accordance with an example embodiment of the present inventive concept.

Referring to FIG. 6, a lower circuit pattern may be formed on a substrate 100. A lower insulating interlayer 102 may be formed to cover the lower circuit patterns.

A common plate electrode layer may be formed on the lower insulating interlayer 102. A common source plate 104 may be formed by patterning the common plate electrode layer. The common plate electrode layer may be formed by, e.g., a chemical vapor deposition (CVD) process or an atomic layer deposition (ALD) process.

Insulation layers 110 and sacrificial layers 112 may be alternately and repeatedly formed on the common source plate 104 to form a preliminary stacked layer 114. The sacrificial layer 112 may have a high etch selectivity with respect to the insulation layer 110. In example embodiments, the insulation layer 110 may include, e.g., silicon oxide, and the sacrificial layer 112 may include, e.g., silicon nitride. The number of stacked insulation layers 110 and sacrificial layers 112 may vary according to example embodiments.

An uppermost insulation layer 110 may be disposed at an uppermost layer of the preliminary stacked layer 114. In example embodiments, a thickness of the uppermost insulation layer 110 may be greater than the insulation layer 110 disposed therebelow.

In some example embodiments, processes for forming the lower insulating interlayer 102 and the common source plate 104 are not performed. As a result, the preliminary stacked layer 114 may be formed directly on the substrate 100.

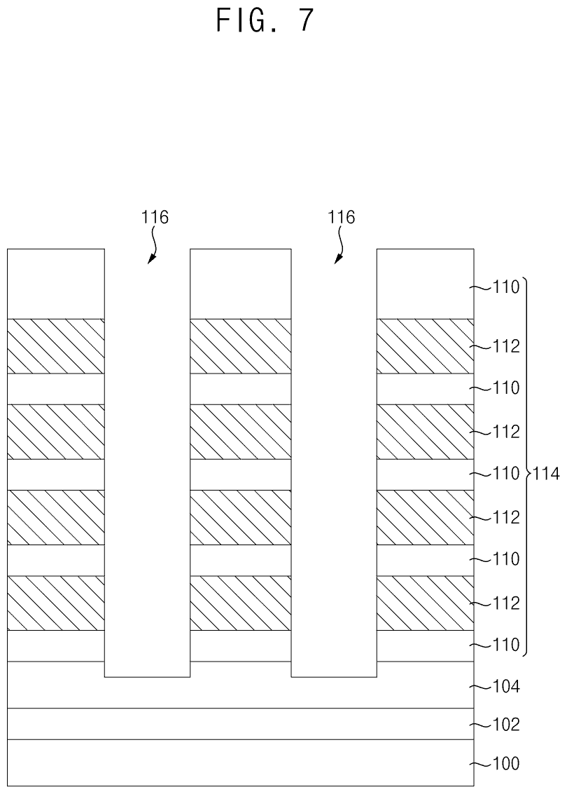

Referring to FIG. 7, the preliminary stacked layer 114 may be anisotropically etched to form channel holes 116 passing through the preliminary stacked layer 114 and exposing an upper portion of the common source plate 104.

In example embodiments, the channel holes 116 may be regularly arranged.

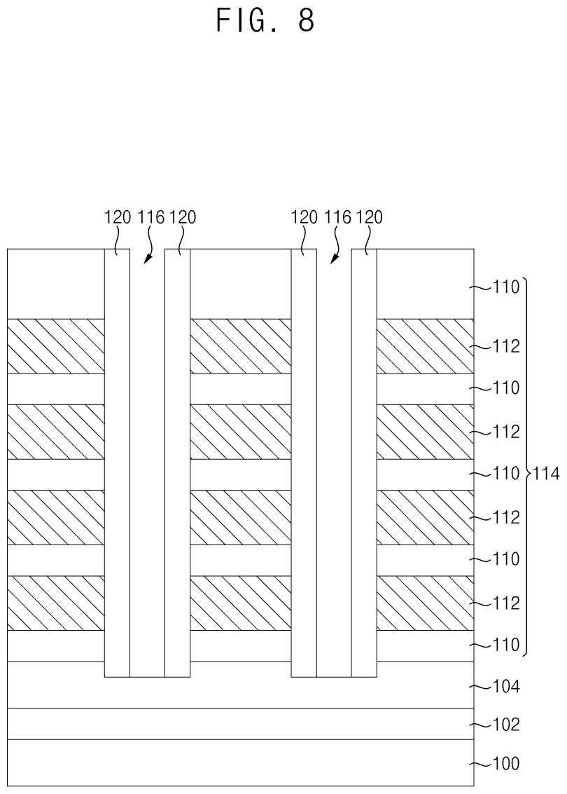

Referring to FIG. 8, an insulation layer may be conformally formed on a sidewall and a bottom of each of the channel holes 116 and an upper surface of the preliminary stacked layer, and the insulation layer may be anisotropically etched to form a preliminary gate insulation layer 120.

The preliminary gate insulation layer 120 may be formed on the sidewall of the channel hole 116. The preliminary gate insulation layer 120 may cover the insulation layers 110 and sacrificial layers 112 in the preliminary stacked layer 114 exposed by the channel hole 116. The common source plate 104 may be exposed by a bottom of the channel hole 116.

The preliminary gate insulation layer 120 may include a metal oxide having a high dielectric constant. In example embodiments, the preliminary gate insulation layer 120 may include a metal oxide that can be converted into a ferroelectric material depending on a crystal structure thereof.

In example embodiments, the preliminary gate insulation layer 120 does not include dopants. The preliminary gate insulation layer 120 may include the metal oxide having no dopant. For example, the preliminary gate insulation layer 120 may include hafnium oxide having no dopant.

The metal oxide included in the preliminary gate insulation layer 120 may have paraelectricity. Since the dopants are not included in the preliminary gate insulation layer 120, it may be difficult to induce the preliminary gate insulation layer 120 to have ferroelectricity.

In example embodiments, the preliminary gate insulation layer 120 may be formed by an ALD process or a CVD process.

For example, the preliminary gate insulation layer 120 may include hafnium oxide formed by the ALD process. In this case, a deposition cycle including hafnium precursor introduction, purge, oxygen source introduction, and purge processes may be performed several times to form the preliminary gate insulation layer 120.

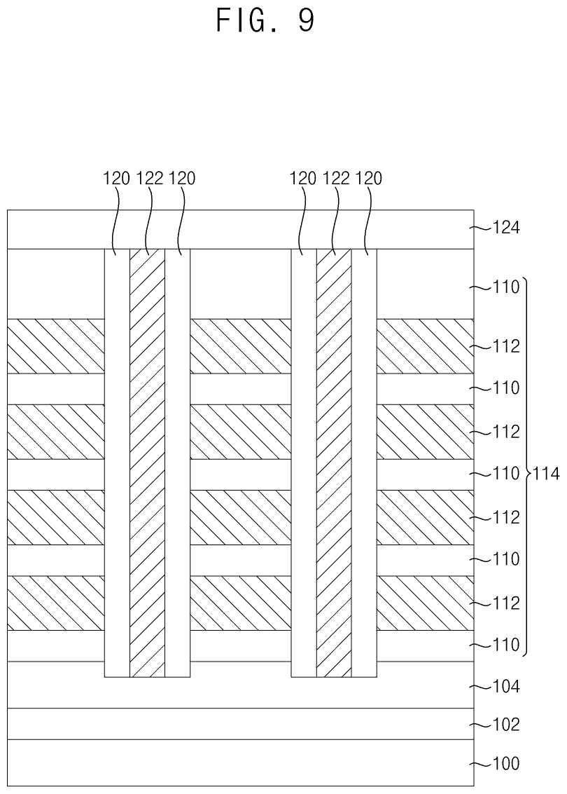

Referring to FIG. 9, a channel layer may be formed on the preliminary gate insulation layer 120, the common source plate 104, and the preliminary stacked layer 114 to fill the channel hole 116. In example embodiments, the channel layer may be formed by an ALD process or a CVD process.

The channel layer may be planarized until an upper surface of the preliminary stacked layer 114 is exposed to form a channel pattern 122 filling the channel hole 116. Accordingly, the channel pattern 122 may have a pillar shape filling the channel hole 116. The channel pattern 122 may include polysilicon.

In some example embodiments, as shown in FIG. 5, the channel pattern 122 may have a cylindrical shape. In this case, the channel pattern 122 may be conformally formed along a sidewall and bottom of the channel hole 116, and a filling insulation layer may be formed on the channel pattern 122 to fill the channel hole 116. Additionally, an upper portion of the filling insulation layer may be etched to form a recess at an upper portion of the channel hole 116, and an upper capping pattern 125 may be formed in the recess. The upper capping pattern 125 may be electrically connected to the channel pattern 122. The upper capping pattern 125 may include polysilicon.

In some example embodiments, before forming the channel pattern 122, a first interface insulation layer 128 (refer to FIG. 3) may be further formed on the preliminary gate insulation layer 120. The first interface insulation layer 128 may include, e.g., silicon oxide or aluminum oxide.

After forming the channel pattern 122, a first insulating interlayer 124 may be formed on the preliminary stacked layer 114 and the channel pattern 122.

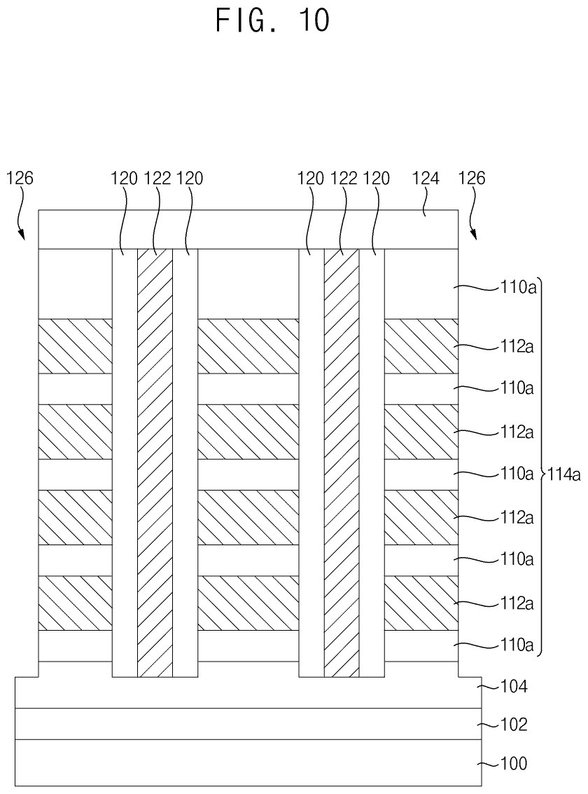

Referring to FIG. 10, the first insulating interlayer 124 and the preliminary stacked layer 114 may be anisotropically etched to form a trench passing through the first insulating interlayer 124 and the preliminary stacked layer 114 and exposing the upper portion of the common source plate 104. The trench 126 may have a line shape extending in the first direction.

The preliminary stacked layer 114 may be separated by the etching process to form a preliminary stacked structure 114a. The preliminary stacked structure 114a may have insulation patterns 110a and sacrificial patterns 112a alternately and repeatedly stacked. The preliminary stacked structure 114a may have a line shape extending in the first direction.

Sidewalls of the insulation patterns 110a and the sacrificial patterns 112a in the preliminary stack structure 114a may be exposed by sidewalls of the trench 126.

In example embodiments, a plurality of preliminary stacked structures 114a may be formed, and the trench 126 may be formed between the preliminary stacked structures 114a.

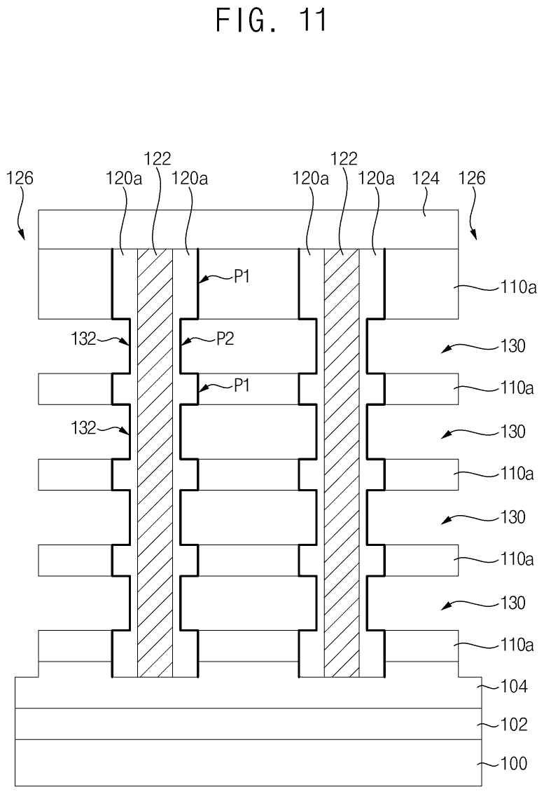

Referring to FIG. 11, the sacrificial patterns 112a included in the preliminary stack structure 114a may be selectively removed to form gaps between the insulation patterns 110a in the vertical direction. A portion of the preliminary gate insulation layer 120 may be exposed by the gaps.

The portion of the preliminary gate insulation layer 120 exposed by the gap may be partially etched to form a gate insulation layer 120a including a first recess 132. A first gap 130 may be formed between the insulation patterns 110a in the vertical direction.

In example embodiments, in the etching process, the preliminary gate insulation layer 120 exposed by the gap is not completely etched, and a predetermined thickness of the preliminary gate insulation layer may remain to form the gate insulation layer 120a. Therefore, in example embodiments, a sidewall of the channel pattern 122 is not exposed by the first gap 130 after the etching process. Additionally, excessive etching of a portion of the preliminary gate insulation layer 120 facing the adjacent insulation patterns 110a may be prevented. Additionally, damage to the channel pattern 122 due to exposure of the channel pattern 122 may be prevented.

A portion of the gate insulation layer 120a that contacts the sidewall of the insulation pattern 110a may be a first portion P1 having no first recess 132. A portion of the gate insulation layer 120a exposed by the first gap 130 may be a second portion P2 including the first recess 132. A thickness in a lateral direction (e.g., a lateral thickness) of the second portion P2 may be less than a thickness in a lateral direction (e.g., a lateral thickness) of the first portion P1. The thickness of the first portion P1 may be greater than about three times the thickness of the second portion P2.

Accordingly, the gate insulation layer 120a may have the first portion P1 and the second portion P2 alternately disposed in the vertical direction. The gate insulation layer 120a may include a first metal oxide layer that has paraelectricity and is not doped with dopants.

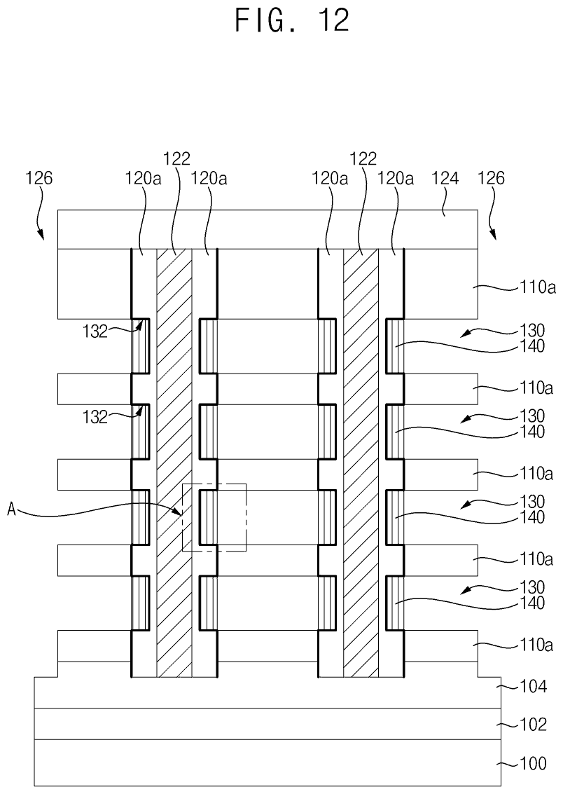

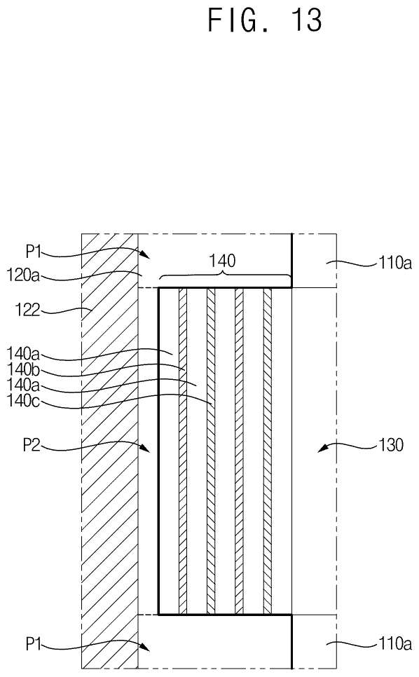

Referring to FIGS. 12 and 13, a gate insulation pattern 140 may be formed to fill the first recess 132 of the second portion P2 of the gate insulation layer 120a through the first gap 130. The gate insulation pattern 140 may include a ferroelectric material.

In example embodiments, the gate insulation pattern 140 may include second metal oxide layers 140a and doped layers 140b and 140c. In this case, the gate insulation pattern 140 may include the second metal oxide layers 140a and doped layers 140b and 140c alternately stacked. At this time, a thickness of each of the second metal oxide layers may be less than a thickness of each of the doped layers 140b and 140c. The second metal oxide layer may be a ferroelectric metal oxide layer.

Each of the doped layers 140b and 140c may be an oxide layer of a material used as dopants. The dopants may include, e.g., silicon (Si), zirconium (Zr), aluminum (Al), yttrium (Y), lanthanum (La), carbon (C), nitrogen (N), germanium (Ge), and tin (Sn).), strontium (Sr), lead (Pb), calcium (Ca), barium (Ba), titanium (Ti), zirconium (Zr), gadolinium (Gd), etc.

The gate insulation pattern 140 may be selectively and laterally formed on a first surface of the second portion P2 of the gate insulation layer 120a by a lateral deposition process. In some example embodiments, the gate insulation pattern 140 on the surface of the insulation pattern 110a may be formed to have a thickness less than a thickness of the gate insulation pattern 140 on the first surface of the second portion P2 of the gate insulation layer 1120a. In example embodiments, a removing process (e.g., a cleaning process) of the gate insulation pattern 140 disposed on the surface of the insulation pattern 110a may be further performed.

As shown in FIG. 12, a surface of the gate insulation pattern 140 may be vertically aligned with the first surface of the first portion P1 of the gate insulation layer 120a. In some example embodiments, the surface of the gate insulation pattern 140 may slightly and laterally protrude from the first surface of the first portion P1 of the gate insulation layer 120a.

In example embodiments, the gate insulation pattern 140 may be formed by an ALD process.

In example embodiments, in the gate insulation pattern 140, the second metal oxide layer may include a hafnium oxide layer 140a, and the doped layers may include a zirconium oxide layer 140b and a silicon oxide layer 140c. For example, the gate insulation pattern 140 may be a stacked structure of the hafnium oxide layer 140a/the zirconium oxide layer 140b/the hafnium oxide layer 140a/the silicon oxide layer 140c. In this case, a thickness of each of hafnium oxide layers 140a may be greater than a thickness of each of the zirconium oxide layer 140b and the silicon oxide layer 140c.

For example, a first deposition cycle including hafnium precursor introduction, purge, oxygen source introduction, and purge processes may be performed several times to form a hafnium oxide layer 140a having a third thickness. A second deposition cycle including zirconium precursor introduction, purge, oxygen source introduction, and purge processes may be performed on the hafnium oxide layer 140a several times to form a zirconium oxide layer 140b having a fourth thickness less than the third thickness. At this time, the number of times the second deposition cycle is performed may be smaller than the number of times the first deposition cycle is performed. The first deposition cycle may be performed on the zirconium oxide layer 140b several times to form the hafnium oxide layer 140a having the third thickness. Thereafter, a third deposition cycle including silicon source introduction, purge, oxygen source introduction, and purge processes may be performed on the hafnium oxide layer 140a several times to form a silicon oxide layer 140c having a fifth thickness less than the third thickness. At this time, the number of times the third deposition cycle is performed may be smaller than the number of times the first deposition cycle is performed.

In some example embodiments, as shown in FIG. 2B, a ferroelectric material having a perovskite structure may be deposited to form the gate insulation pattern 140. In this case, the gate insulation pattern 140 may include, e.g., SBT, BLT, or PZT.

In some example embodiments, a hafnium zirconium oxide may be deposited to form the gate insulation pattern 140.

In some example embodiments, a second interface insulation layer 148 (refer to FIG. 4) may be further selectively formed on the surface of the gate insulation pattern 140 in the first gap 130. In some example embodiments, a second interface insulation layer 148 may be further conformally formed on surfaces of the gate insulation pattern 140 and the insulation pattern 110a in the first gap 130. The second interface insulation layer 148 may include, e.g., silicon oxide or aluminum oxide.

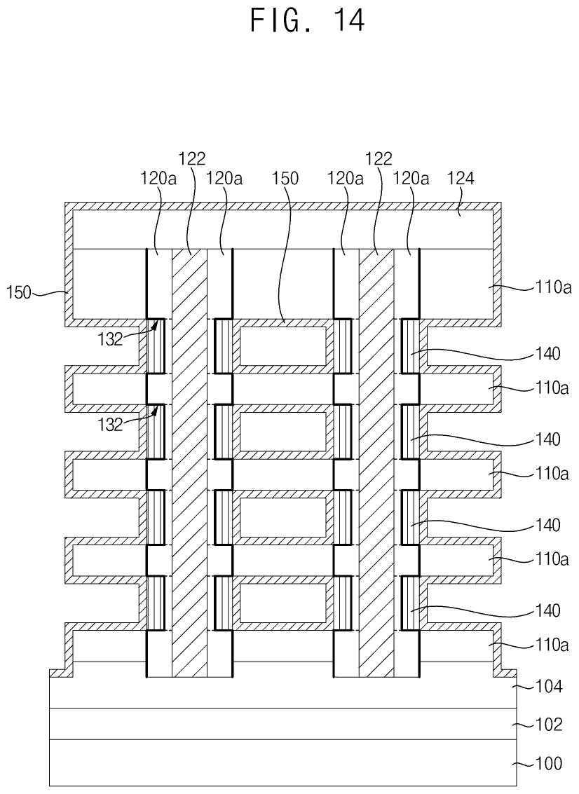

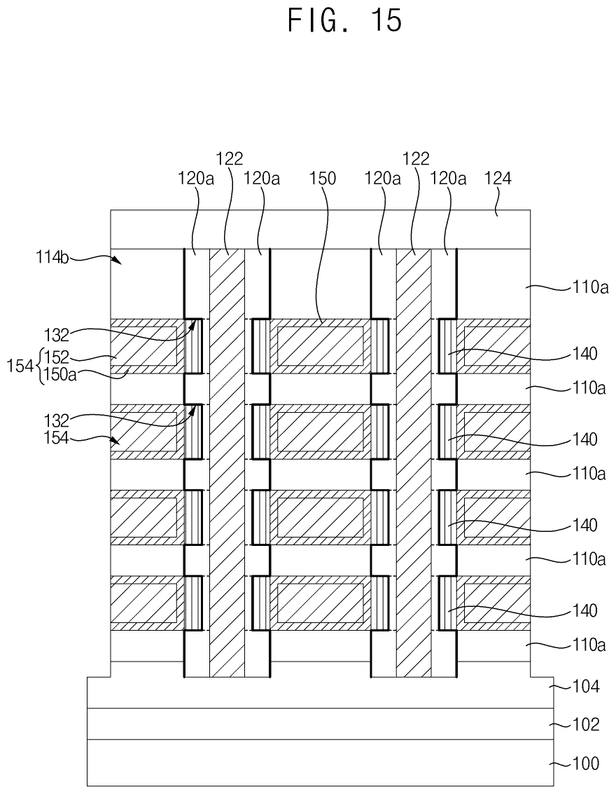

Referring to FIGS. 14 and 15, a gate electrode structure 154 may be formed to fill the first gap 130, and the gate electrode structure 154 may contact the first surface of the gate insulation pattern 140. The gate electrode structure 154 may include metal or polysilicon. As shown in FIG. 14, a stacked structure may be formed in which the gate electrode structures 154 and the insulation patterns 110a are alternately and repeatedly stacked on the substrate 100 in a vertical direction perpendicular (e.g., substantially perpendicular) to a surface of the substrate 100.

For example, as shown in FIG. 14, a barrier metal layer 150 may be conformally formed on surfaces of the insulation patterns 110a in the first gap 130, the first surface of the gate insulation pattern 140, sidewalls of the insulation patterns in the trench 126, and an upper surface of the first insulating interlayer 124. The barrier metal layer 150 may include, e.g., titanium, titanium nitride, tantalum, or tantalum nitride.

Thereafter, a crystallization heat treatment may be performed. In example embodiments, the crystallization heat treatment may be performed in an oxygen atmosphere or an inert gas atmosphere at a temperature of about 400° C. to about 1000° C. The inert gas atmosphere may be a nitrogen atmosphere or an argon atmosphere.

When the crystallization heat treatment is performed, the gate insulation pattern 140 contacting the barrier metal layer 150 may be converted into a crystal structure having ferroelectricity. Meanwhile, the first and second portions P1 and P2 of the gate insulation layer 120a having no dopants does not have ferroelectricity, but, rather, has paraelectricity.

During the crystallization heat treatment, the barrier metal layer 150 may prevent diffusing of the dopants included in the gate insulation pattern 140. Additionally, during the crystallization heat treatment process, the dopants may induce the crystal structure of the material in the gate insulation pattern 140 to have the crystal structure having ferroelectricity.

According to the above process, the first and second portions P1 and P2 of the gate insulation layer 120a may have the first metal oxide having no dopants and having paraelectricity, e.g., hafnium oxide. The gate insulation pattern 140 may be selectively disposed only on the second portion P2 of the gate insulation layer 120a, and may have the second metal oxide layer including dopants and having ferroelectricity.

In example embodiments, when the crystallization heat treatment process is performed, the first portion P1 of the gate insulation layer 120a does not contact the barrier metal layer 150. Additionally, the gate insulation layer 120a does not include dopants to induce ferroelectricity thereof. Therefore, when the crystallization heat treatment process is performed, the first portion P1 of the gate insulation layer 120a is not converted to have ferroelectricity.

When the gate insulation layer 120a and the gate insulation pattern 140 include hafnium oxide, the gate insulation pattern 140 may have a crystal structure of an orthorhombic system. In addition, the first and second portions P1 and P2 of the gate insulation layer 120a may have a crystal structure other than the orthorhombic crystal structure. For example, the first and second portions P1 and P2 of the gate insulation layer 120a may have a crystal structure of a tetragonal system or a monoclinic system.

As shown in FIG. 15, a metal layer may be formed on the barrier metal layer 150 to fill the first gap 130. In example embodiments, the metal layer may be conformally formed and does not completely fill the trench 126. The metal layer may include, e.g., tungsten (W), molybdenum (Mo), cobalt (Co), or ruthenium (Ru).

The barrier metal layer 150 and the metal layer disposed on sidewalls and the bottom of the trench 126 may be removed to form a gate electrode structure 154 including the barrier metal pattern 150a and the metal pattern 152. Accordingly, the preliminary stacked structure 114a may be converted into a stacked structure 114b in which the insulation patterns 110a and the gate electrode structures 154 are alternately and repeatedly stacked.

In some example embodiments, the gate electrode structure 154 may include polysilicon. In this case, a polysilicon layer may be formed to fill the first gap 130, and the polysilicon layer disposed on the sidewalls and the bottom of the trench 126 may be removed to form the gate electrode structure 154. During formation of the polysilicon layer, the crystallization heat treatment may be performed at substantially the same time. Accordingly, the gate insulation pattern 140 contacting the polysilicon layer may be converted into a ferroelectric material.

In some example embodiments, the crystallization heat treatment process is not performed after forming the barrier metal layer 150, but may be performed after forming the metal layer or after forming the gate electrode structure 154.

In some example embodiments, the crystallization heat treatment process may be performed after forming the barrier metal layer 150, and the crystallization heat treatment may be additionally performed after forming the metal pattern 152.

In some example embodiments, the gate insulation pattern 140 may be formed by depositing a ferroelectric material having a perovskite structure. In this case, in example embodiments, the crystallization heat treatment process is not performed.

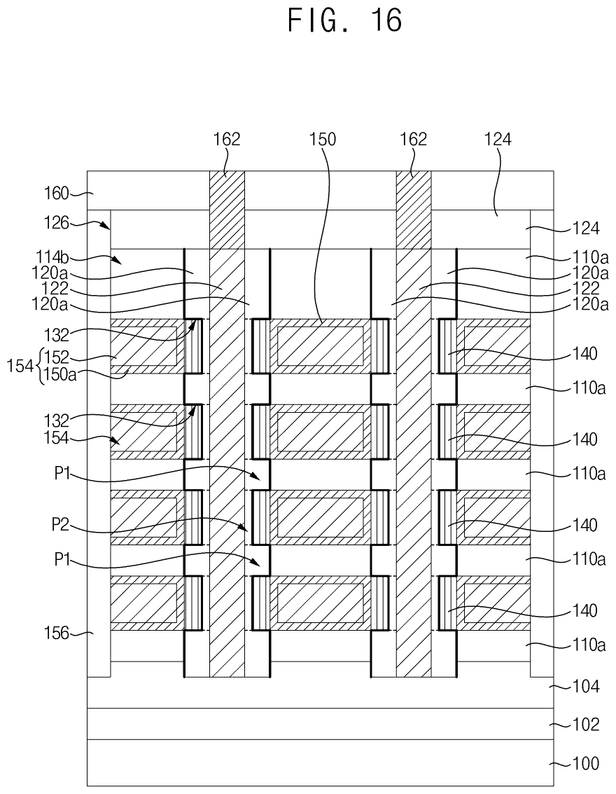

Referring to FIG. 16, a filling insulation pattern 156 may be formed to fill the trench 126. The filling insulation pattern 156 may include, e.g., silicon oxide or silicon nitride.

A second insulating interlayer 160 may be formed on the first insulating interlayer 124.

Thereafter, a connection pattern 162 may be formed through the first and second insulating interlayers 124 and 160. The connection pattern 162 may be electrically connected to the channel pattern 122. The connection pattern 162 may serve as a bit line structure.

As described above, the vertical semiconductor device according to example embodiments may be manufactured.

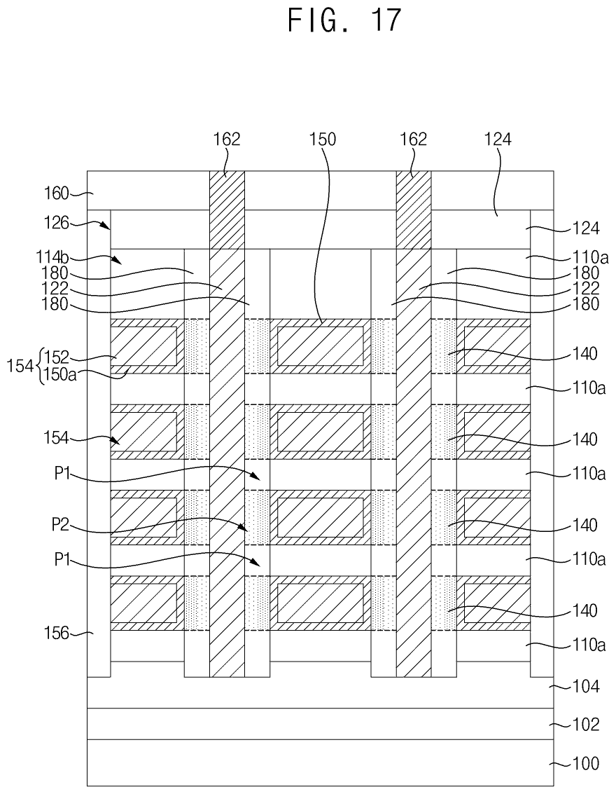

FIG. 17 is a cross-sectional view illustrating a vertical semiconductor device in accordance with an example embodiment of the present inventive concept.

The vertical semiconductor device may be the same as the vertical semiconductor device described with reference to FIG. 1, except for portions of a memory cell.

Referring to FIG. 17, a gate insulation layer 180 may surround the channel pattern 122. The gate insulation layer 180 may contact the channel pattern 122. The gate insulation layer 180 may include a metal oxide having ferroelectricity depending on a crystal structure thereof. The gate insulation layer 180 may include, e.g., hafnium oxide.

The gate insulation layer 180 may include a first portion P1 laterally facing the insulation pattern 110a and a second portion P2 laterally facing the gate electrode structure 154. The first portion P1 and the second portion P2 may be alternately arranged in the vertical direction. The first portion P1 and the second portion P2 of the gate insulation layer 180 may have substantially the same thickness in a lateral direction. Accordingly, in example embodiments, the gate insulation layer 180 does not include the first recess.

In example embodiments, the first portion P1 of the gate insulation layer 180 may include a first metal oxide that may has paraelectricity and is not doped with dopants, and the second portion P2 of the gate insulation layer 180 may have a second metal oxide that has ferroelectricity and is doped with dopants.

A dopant concentration of the dopants included in the gate insulation layer 180 may gradually decrease in a direction from a portion contacting the gate electrode structure 154 toward the channel pattern 122. That is, a portion of the gate insulation layer 180 adjacent to the gate electrode structure 154 may have relatively high dopant concentration. In example embodiments, the second portion P2 of the gate insulation layer 180 adjacent to the channel pattern 122 is not doped with the dopants.

In example embodiments, the first portion P1 of the gate insulation layer 180 may include hafnium oxide that has paraelectricity and is not doped with dopants, and the second portion P2 of the gate insulation layer 180 may include hafnium oxide that has ferroelectricity and is doped with dopants, e.g., silicon or zirconium. In example embodiments, a portion of the second portion P2 of the gate insulation layer 180 adjacent to the channel pattern 122 may include hafnium oxide that is not doped with dopants.

In example embodiments, the gate insulation pattern is not provided.

The gate electrode structure 154 may be disposed between the insulation patterns 110a to fill the first gap 130. The gate electrode structure 154 may contact the second portion P2 of the gate insulation layer 180.

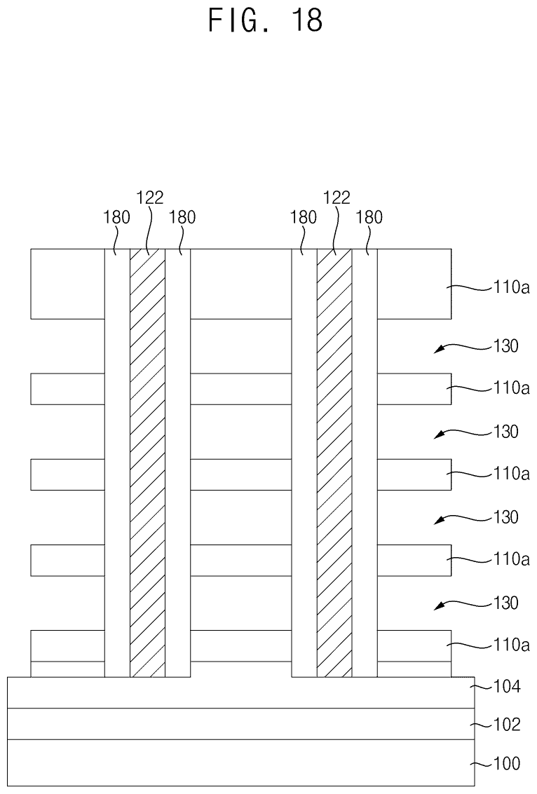

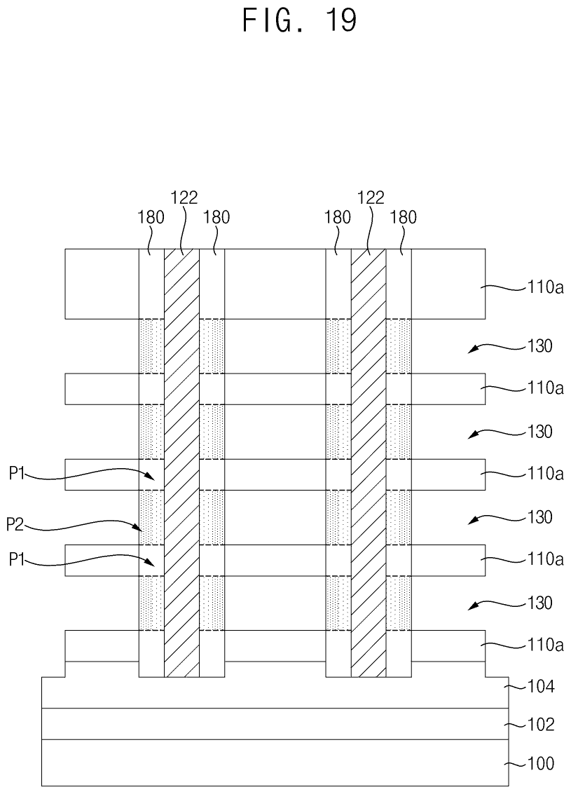

FIGS. 18 and 19 are cross-sectional views illustrating a method of manufacturing a vertical semiconductor device in accordance with an example embodiment of the present inventive concept.

Referring to FIG. 18, first, the processes as described above with reference to FIGS. 6 to 10 may be performed.

The sacrificial patterns 112a included in the preliminary stacked structure 114a are selectively removed to form first gaps 130 between the insulation patterns 110a in the vertical direction. The preliminary gate insulation layer 120 may be exposed by the first gap 130.

Referring to FIG. 19, dopants may be injected through the first gap 130 so that an exposed portion of the preliminary gate insulation layer 120 may be doped to form a gate insulation layer 180.

A second portion P2 of the gate insulation layer 180 exposed by the first gap 130 may be selectively doped with the dopants. In the doping process, a dopant concentration included in the gate insulation layer 180 may be gradually decreased in a direction from a potion contacting the gate electrode structure 154 toward the channel pattern 122. In example embodiments, in the second portion P2 of the gate insulation layer 180, a portion adjacent to the channel pattern 122 is not doped with the dopants.

Meanwhile, in example embodiments, the first portion P1 of the gate insulation layer 180 contacting the insulation pattern 110a is not doped with the dopants.

The dopant injection process may be performed by a plasma doping process (PLAD). According to the plasma doping process, the dopants may be selectively doped along an exposed surface of a layer.

In example embodiments, the first portion P1 of the gate insulation layer 180 may include hafnium oxide that has paraelectricity and is not doped with dopants, and in the second portion P2 of the gate insulation layer 180, the portion adjacent to the channel pattern 122 may include hafnium oxide that has paraelectricity and is not doped with dopants. In the second portion P2 of the gate insulation layer 180A, a portion except for the portion adjacent to the channel pattern 122 may include hafnium oxide that has ferroelectricity and is doped with dopants, e.g., silicon or zirconium.

The processes described above with reference to FIGS. 13 to 16 may be performed to manufacture the vertical semiconductor device shown in FIG. 17.

The vertical semiconductor devices according to example embodiments may be used as, for example, memories included in electronic products such as mobile devices, memory cards, and computers.

In an example embodiment of the present inventive concept, a three dimensional (3D) memory array is provided. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array. In an example embodiment of the present inventive concept, the 3D memory array includes vertical NAND strings that are vertically oriented such that at least one memory cell is located over another memory cell. The at least one memory cell may include a charge trap layer. The following patent documents, which are hereby incorporated by reference, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and US Pat. Pub. No. 2011/0233648.

While the present inventive concept has been described with reference to example embodiments thereof, it will be understood by those of ordinary skill in the art that various changes in form and details may be made thereto without departing from the spirit and scope of the present inventive concept as defined by the following claims.

What is claimed is:

1. A vertical semiconductor device, comprising:
a substrate;
a stacked structure including a plurality of insulation patterns and a plurality of gate electrode structures alternately and repeatedly stacked on the substrate in a vertical direction substantially perpendicular to a surface of the substrate;
a channel pattern passing through the stacked structure;
a gate insulation layer surrounding an outer wall of the channel pattern,
wherein the gate insulation layer includes a metal oxide having paraelectricity; and
a gate insulation pattern disposed between the gate insulation layer and the gate electrode structures,
wherein the gate insulation pattern has ferroelectricity,
wherein the gate insulation layer includes a first portion contacting one of the insulation patterns and a second portion contacting the gate insulation pattern.

2. The vertical semiconductor device of claim 1, wherein a thickness of the second portion of the gate insulation layer is less than a thickness of the first portion of the gate insulation layer.

3. The vertical semiconductor device of claim 1, wherein the first portion and the second portion of the gate insulation layer are repeatedly arranged in the vertical direction, and
the second portion of the gate insulation layer includes a first recess in a direction toward the channel pattern.

4. The vertical semiconductor device of claim 3, wherein the gate insulation pattern is disposed in the first recess of the gate insulation layer.

5. The vertical semiconductor device of claim 1, wherein the first portion of the gate insulation layer does not directly contact any of the gate electrode structures.

6. The vertical semiconductor device of claim 1, wherein the gate insulation layer includes hafnium oxide that is not doped with a dopant.

7. The vertical semiconductor device of claim 1, wherein the gate insulation pattern includes a plurality of hafnium oxide layers and a plurality of doped layers alternately stacked.

8. The vertical semiconductor device of claim 7, wherein each of the doped layers is an oxide layer of a material serving as a dopant, and
the dopant includes at least one of silicon (Si), zirconium (Zr), aluminum (Al), yttrium (Y), lanthanum (La), and carbon (C), nitrogen (N), germanium (Ge), tin (Sn), strontium (Sr), lead (Pb), calcium (Ca), barium (Ba), titanium (Ti), zirconium (Zr), or gadolinium (Gd).

9. The vertical semiconductor device of claim 7, wherein the gate insulation pattern includes a structure in which one of the plurality of hafnium oxide layers, a zirconium oxide layer, another one of the plurality of hafnium oxide layers, and a silicon oxide layer are sequentially stacked.

10. The vertical semiconductor device of claim 7, wherein each of the hafnium oxide layers has a thickness greater than a thickness of each of the doped layers.

11. The vertical semiconductor device of claim 1, wherein a thickness of the second portion of the gate insulation layer is less than a thickness of the gate insulation pattern.

12. The vertical semiconductor device of claim 1, wherein the gate insulation pattern includes hafnium zirconium oxide or a ferroelectric material having a perovskite structure.

13. The vertical semiconductor device of claim 1, wherein a surface of the gate insulation pattern is vertically aligned with a surface of the first portion of the gate insulation layer, or laterally protrudes from the surface of the first portion of the gate insulation layer.

14. The vertical semiconductor device of claim 1, further comprising:
at least one of a first interface insulation layer disposed between the channel pattern and the gate insulation layer and a second interface insulation layer disposed between the gate insulation pattern and one of the gate electrode structures.

15. A vertical semiconductor device, comprising:
a substrate;
a stacked structure including a plurality of insulation patterns and a plurality of gate electrode structures alternately and repeatedly stacked on the substrate in a vertical direction substantially perpendicular to a surface of the substrate;
a channel pattern passing through the stacked structure;
a gate insulation layer surrounding an outer wall of the channel pattern,
wherein the gate insulation layer includes a metal oxide having paraelectricity and not having a dopant, and a first portion of the gate insulation layer facing the gate electrode structure includes a first recess in a direction toward the channel pattern; and
a gate insulation pattern disposed in the first recess,
wherein the gate insulation pattern has ferroelectricity,
wherein the first portion the gate insulation layer facing the gate electrode structure has a thickness less than a thickness of the gate insulation pattern.

16. The vertical semiconductor device of claim 15, wherein the gate insulation pattern includes a plurality of hafnium oxide layers and a plurality of doped layers alternately stacked.

17. The vertical semiconductor device of claim 16, wherein each of the hafnium oxide layers has a thickness greater than a thickness of each of the doped layers.

18. The vertical semiconductor device of claim 15, wherein a surface of the gate insulation pattern is vertically aligned with a surface of a second portion of the gate insulation layer facing one of the insulation patterns, or laterally protrudes from the surface of the second portion of the gate insulation layer facing the one of the insulation patterns.

19. A vertical semiconductor device, comprising:
a substrate;
a stacked structure including a plurality of insulation patterns and a plurality of gate electrode structures alternately and repeatedly stacked on the substrate in a vertical direction substantially perpendicular to a surface of the substrate;
a channel pattern passing through the stacked structure;
a gate insulation layer surrounding an outer wall of the channel pattern,
wherein the gate insulation layer includes hafnium oxide having paraelectricity and not having a dopant, and a first portion of the gate insulation layer facing the gate electrode structure includes a first recess in a direction toward the channel pattern; and
a gate insulation pattern disposed in the first recess,
wherein the gate insulation pattern has ferroelectricity,
wherein the gate insulation pattern includes a plurality of hafnium oxide layers and a plurality of doped layers alternately stacked.

20. The vertical semiconductor device of claim 19, wherein the gate insulation pattern includes a structure in which a hafnium oxide layer among the plurality of hafnium oxide layers, a zirconium oxide layer, another hafnium oxide layer among the plurality of hafnium oxide layers, and a silicon oxide layer are sequentially and repeatedly stacked.
